(19) United States
(12) Patent Application Publication
(10) Pub. No.: US 2024/0030138 A1
(43) Pub. Date: Jan. 25, 2024

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Kuo-Chiang TSAI, Hsinchu City (TW); Jeng-Ya YEH, Hsinchu City (TW); Mu-Chi CHIANG, Hsinchu (TW)

(21) Appl. No.: 17/814,317

(22) Filed: Jul. 22, 2022

(51) Int. Cl. H01L 23/535; H01L 29/08; H01L 29/417; H01L 29/78; H01L 29/06; H01L 29/423; H01L 29/786; H01L 29/775; H01L 29/40; H01L 21/768

(52) U.S. Cl. CPC H01L 23/535; H01L 29/0847; H01L 29/41791; H01L 29/7851; H01L 29/0673; H01L 29/42392; H01L 29/41733; H01L 29/78696; H01L 29/775; H01L 29/401; H01L 21/76805; H01L 21/76895

(57) ABSTRACT

A semiconductor device structure is provided. The semiconductor device structure includes a gate structure formed over a fin structure. The semiconductor device structure includes an S/D structure formed over the fin structure and adjacent to the gate structure, and a first dielectric layer formed over the gate structure and the S/D structure. The semiconductor device structure includes an S/D contact structure formed in the first dielectric layer, and a second dielectric layer formed over the S/D contact structure. The semiconductor device structure includes a first conductive via formed in the second dielectric layer, and the first conductive via is directly over the S/D contact structure or directly over the gate structure. The first conductive via has a protruding portion that is lower than the top surface of the S/D contact structure or lower than the top surface of the gate structure.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

As the semiconductor industry has progressed into nanometer technology process nodes in pursuit of higher device density, higher performance, and lower costs, challenges from both fabrication and design issues have resulted in the development of three-dimensional designs, such as the fin field effect transistor (FinFET). FinFETs are fabricated with a thin vertical “fin” (or fin structure) extending from a substrate. The channel of the FinFET is formed in this vertical fin. A gate is provided over the fin. The advantages of a FinFET may include reducing the short channel effect and providing a higher current flow.

Although existing FinFET devices and methods of fabricating FinFET devices have generally been adequate for their intended purpose, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1K show perspective representations of various stages of forming a semiconductor device structure, in accordance with some embodiments of the disclosure.

FIG. 2 shows a top view of the semiconductor device structure, in accordance with some embodiments of the disclosure.

FIG. 3A shows a cross-sectional representation taken along line I-I′ of FIG. 1K.

FIGS. 3B-3F show cross-sectional representations of various stages of forming a semiconductor device structure after the structure of FIG. 3A, in accordance with some embodiments of the disclosure.

FIGS. 4A-4B show cross-sectional representations of various stages of forming a semiconductor device structure, in accordance with some embodiments of the disclosure.

FIG. 5 shows a cross-sectional representation of a semiconductor device structure, in accordance with some embodiments of the disclosure.

FIGS. 6A-6B show cross-sectional representations of various stages of forming a semiconductor device structure, in accordance with some embodiments of the disclosure.

FIGS. 7A-7B show cross-sectional representations of various stages of forming a semiconductor device structure, in accordance with some embodiments of the disclosure.

FIG. 8 shows a cross-sectional representation of a semiconductor device structure, in accordance with some embodiments of the disclosure.

FIG. 9 shows a cross-sectional representation of a semiconductor device structure, in accordance with some embodiments of the disclosure.

FIGS. 10A-10B show cross-sectional representations of various stages of forming a semiconductor device structure, in accordance with some embodiments of the disclosure.

FIG. 11 shows a top view of a semiconductor device structure, in accordance with some embodiments of the disclosure.

FIGS. 12A-12B show cross-sectional representations of various stages of forming a semiconductor device structure, in accordance with some embodiments of the disclosure.

FIG. 13 shows a top view of the semiconductor device structure, in accordance with some embodiments of the disclosure.

FIG. 14 shows a cross-sectional representation taken along line C-C′ of FIG. 13.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-alignment process. The sacrificial layer is then removed, and the remaining spacers may then be used to pattern the fins.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of semiconductor structures and methods for forming the same are provided. The semiconductor structures may include a fin structure formed over a substrate. A gate structure formed over the fin, and an S/D structure adjacent to the gate structure. A first dielectric layer formed over the gate structure, and a second dielectric layer formed over the first dielectric layer. An S/D contact structure formed over the S/D structure and through the first dielectric layer. A conductive via formed over the S/D contact structure. The conductive via extends from the second dielectric layer to the first dielectric layer. The conductive via has a protruding portion which is embedded in the first dielectric layer. A portion of the sidewall of the S/D contact structure is covered by the conductive via, and the contact area between the conductive via and the S/D contact structure is improved. The conductive via may be directly over the gate structure, and has protruding portion lower than the top surface of the gate structure. In addition, the conductive via is formed in an interconnect structure. The conductive via has protruding portion downwardly from the top surface of the conductive layer. Therefore, the reliability and the performance of the semiconductor structure are improved. In some embodiments, the fin structure includes a number of nanostructures, and the gate structure wraps around the nanostructures. The source/drain(S/D) structure or region(s) may refer to a source or a drain, individually or collectively dependent upon the context.

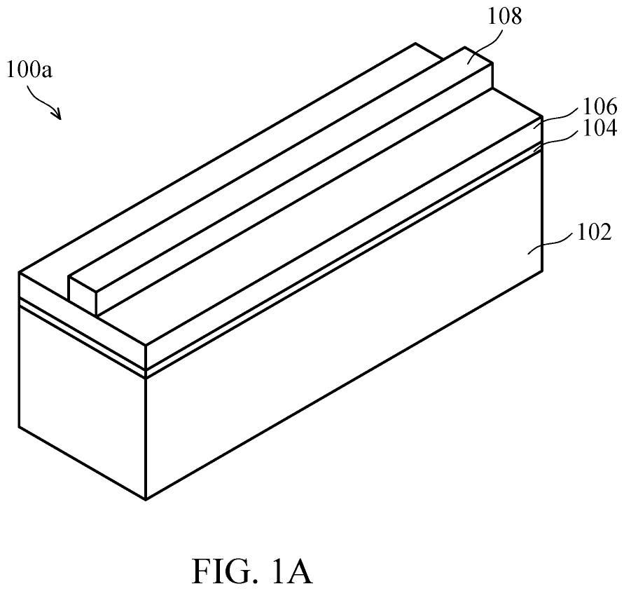

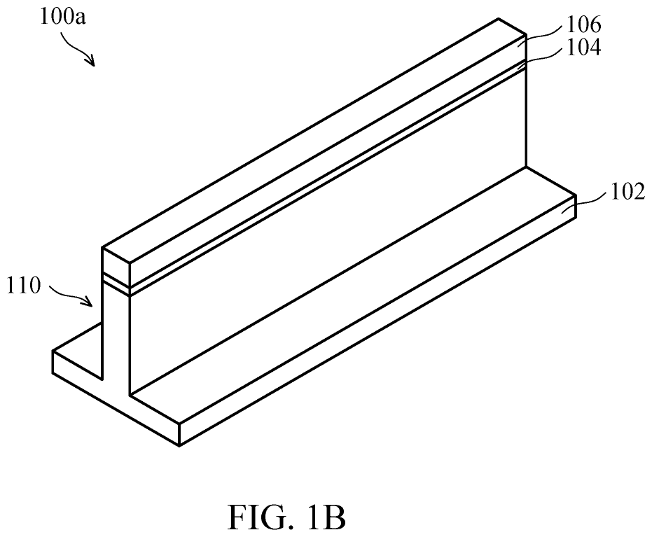

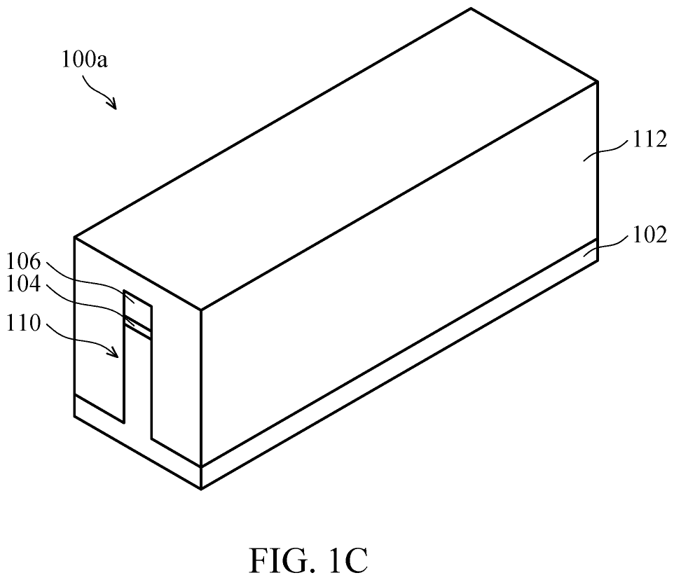

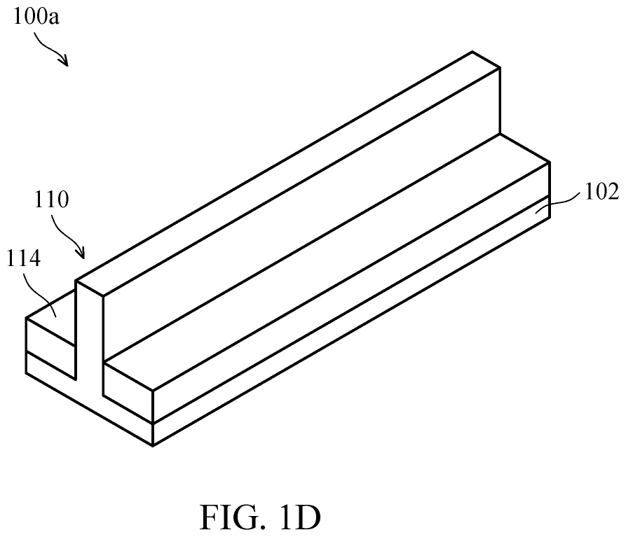

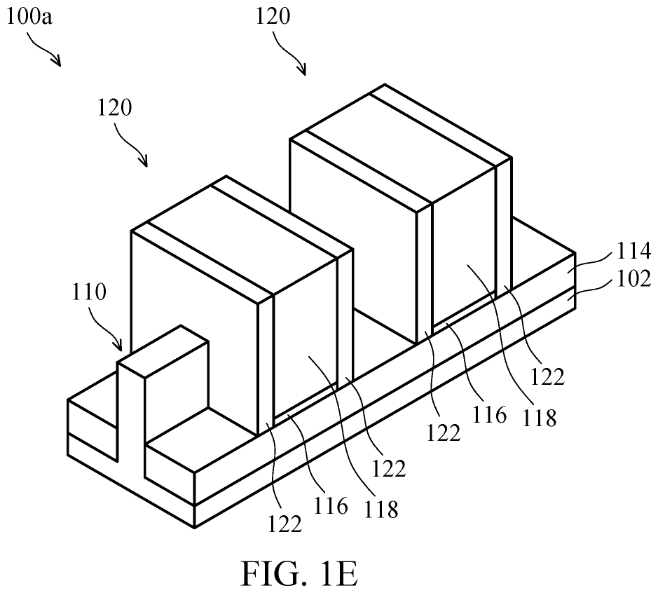

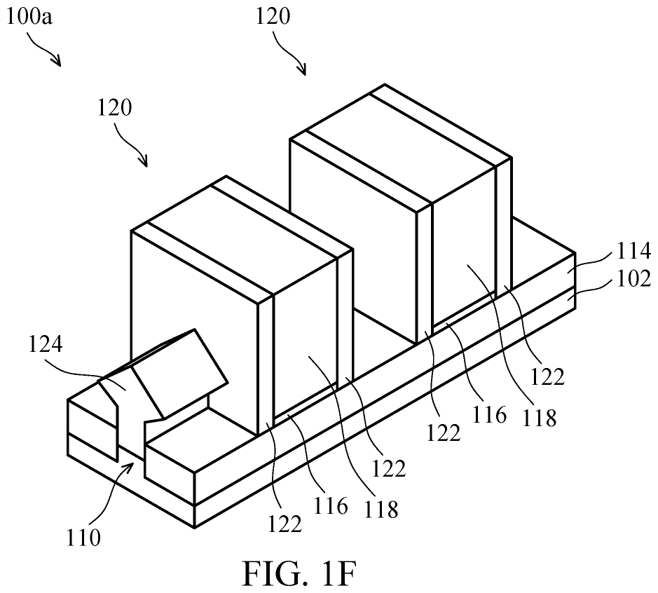

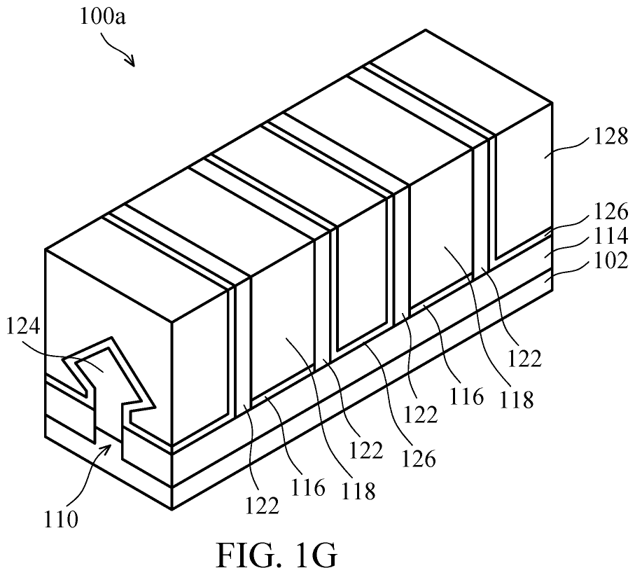

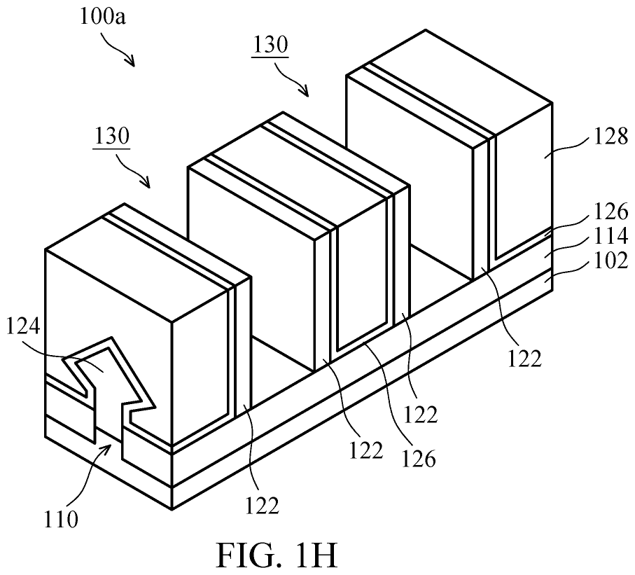

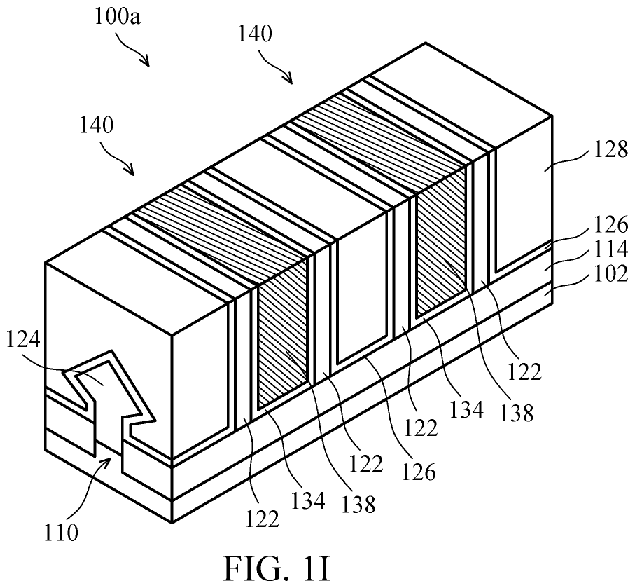

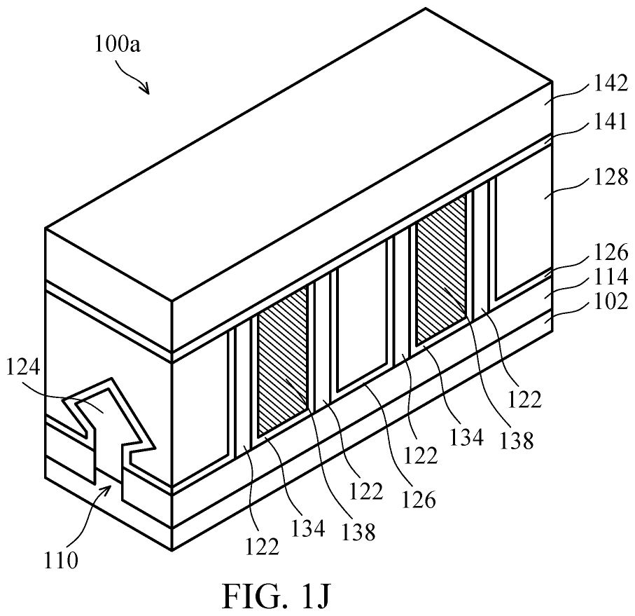

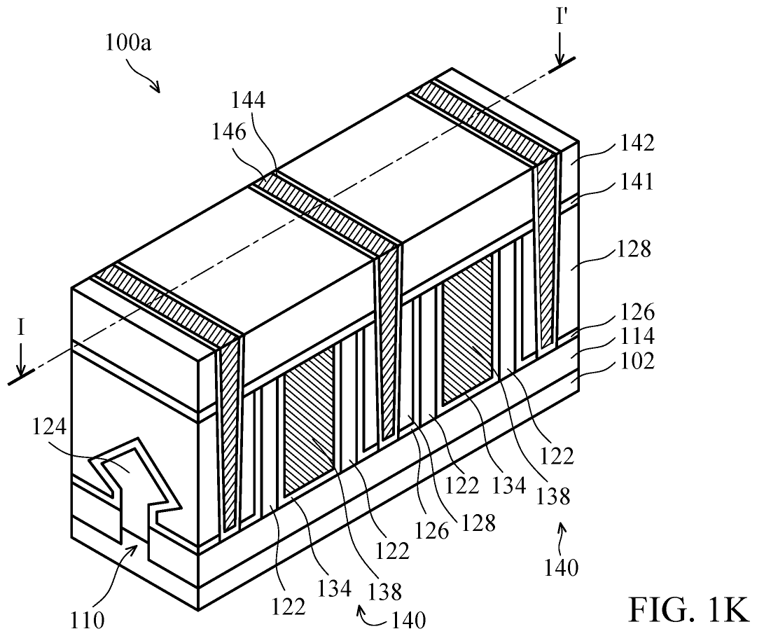

Embodiments for forming a semiconductor device structure are provided. FIGS. 1A-1K show perspective representations of various stages of forming a semiconductor device structure 100a, in accordance with some embodiments of the disclosure.

Referring to FIG. 1A, a substrate 102 is provided. The substrate 102 may be made of silicon or other semiconductor materials. Alternatively or additionally, the substrate 102 may include other elementary semiconductor materials such as germanium. In some embodiments, the substrate 102 is made of a compound semiconductor such as silicon carbide, gallium arsenic, indium arsenide, or indium phosphide. In some embodiments, the substrate 102 is made of an alloy semiconductor such as silicon germanium, silicon germanium carbide, gallium arsenic phosphide, or gallium indium phosphide. In some embodiments, the substrate 102 includes an epitaxial layer. For example, the substrate 102 has an epitaxial layer overlying a bulk semiconductor.

Afterwards, a dielectric layer 104 and a mask layer 106 are formed over the substrate 102, and a photoresist layer 108 is formed over the mask layer 106. The photoresist layer 108 is patterned by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

The dielectric layer 104 is a buffer layer between the substrate 102 and the mask layer 106. In addition, the dielectric layer 104 is used as a stop layer when the mask layer 106 is removed. The dielectric layer 104 may be made of silicon oxide. The mask layer 106 may be made of silicon oxide, silicon nitride, silicon oxynitride, or another applicable material. In some other embodiments, more than one mask layer 106 is formed over the dielectric layer 104.

The dielectric layer 104 and the mask layer 106 are formed by deposition processes, such as a chemical vapor deposition (CVD) process, a high-density plasma chemical vapor deposition (HDPCVD) process, a spin-on process, a sputtering process, or another applicable process.

As shown in FIG. 1B, after the photoresist layer 108 is patterned, the dielectric layer 104 and the mask layer 106 are patterned by using the patterned photoresist layer 108 as a mask, in accordance with some embodiments. As a result, a patterned pad layer 104 and a patterned mask layer 106 are obtained. Afterwards, the patterned photoresist layer 108 is removed.

Next, an etching process is performed on the substrate 102 to form a fin structure 110 by using the patterned dielectric layer 104 and the patterned mask layer 106 as a mask. The etching process may be a dry etching process or a wet etching process.

In some embodiments, the substrate 102 is etched using a dry etching process. The dry etching process includes using a fluorine-based etchant gas, such as SF₆, CₓF_{y}, NF₃ or a combination thereof. The etching process may be a time-controlled process, and continue until the fin structure 110 reaches a predetermined height. In some other embodiments, the fin structure 110 has a width that gradually increases from the top portion to the lower portion.

As shown in FIG. 1C, after the fin structure 110 is formed, an insulating layer 112 is formed to cover the fin structure 110 over the substrate 102, in accordance with some embodiments.

In some embodiments, the insulating layer 112 is made of silicon oxide, silicon nitride, silicon oxynitride, fluoride-doped silicate glass (FSG), low-k dielectric material or another applicable material. The insulating layer 112 may be deposited by a chemical vapor deposition (CVD) process, a spin-on-glass process, or another applicable process.

Afterwards, the insulating layer 112 is thinned or planarized to expose the top surface of the patterned mask layer 106. In some embodiments, the insulating layer 112 is thinned by a chemical mechanical polishing (CMP) process.

Afterwards, as shown in FIG. 1D, the patterned dielectric layer 104 and the patterned mask layer 106, and a portion of the insulating layer 112 is removed by an etching process, in accordance with some embodiments. As a result, an isolation structure 114 is obtained. The isolation structure 114 may be a shallow trench isolation (STI) structure surrounding the fin structure 110. A lower portion of the fin structure 110 is surrounded by the isolation structure 114, and an upper portion of the fin structure 110 protrudes from the isolation structure 114. In other words, a portion of the fin structure 110 is embedded in the isolation structure 114. The isolation structure 114 prevents electrical interference and crosstalk.

Afterwards, as shown in FIG. 1E, a dummy gate structure 120 is formed across the fin structure 110 and extends over the isolation structure 114, in accordance with some embodiments. In some embodiments, the dummy gate structure 120 includes a dummy gate dielectric layer 116 and a dummy gate electrode layer 118 formed over the dummy gate dielectric layer 116. In some embodiments, the dummy gate dielectric layer 116 includes silicon oxide, and the dummy gate electrode layer 118 includes polysilicon. After the dummy gate structure 120 is formed, the gate spacer layers 122 are formed on opposite sidewall surfaces of the dummy gate structure 120. The gate spacer layers 122 may be a single layer or multiple layers.

In order to improve the speed of the semiconductor device structure 100a, the gate spacer layers 122 are made of low-k dielectric materials. In some embodiments, the low-k dielectric materials has a dielectric constant (k value) is less than 4. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

In some other embodiments, the gate spacer layers 122 are made of an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), or porous silicon oxide (SiO₂).

Afterwards, as shown in FIG. 1F, the source/drain (S/D) structures 124 are formed over the fin structure 110, in accordance with some embodiments. In some embodiments, portions of the fin structure 110 adjacent to the dummy gate structure 120 are recessed to form recesses at two sides of the fin structure 110, and a strained material is grown in the recesses by an epitaxial (epi) process to form the S/D structures 124. In addition, the lattice constant of the strained material may be different from the lattice constant of the substrate 102. In some embodiments, the S/D structures 124 include Ge, SiGe, InAs, InGaAs, InSb, GaAs, GaSb, InAlP, InP, or the like.

Afterwards, as shown in FIG. 1G, a contact etch stop layer (CESL) 126 is formed over the substrate 102, and an inter-layer dielectric (ILD) layer 128 is formed over the CESL 126, in accordance with some embodiments. In some other embodiments, the CESL 126 is made of silicon nitride, silicon oxynitride, and/or other applicable materials. The CESL 126 may be formed by plasma enhanced CVD, low-pressure CVD, ALD, or other applicable processes.

The ILD layer 128 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 128 may be formed by chemical vapor deposition (CVD), physical vapor deposition, (PVD), atomic layer deposition (ALD), spin-on coating, or another applicable process.

Afterwards, a polishing process is performed on the ILD layer 128 until the top surface of the dummy gate structure 120 is exposed. In some embodiments, the ILD layer 128 is planarized by a chemical mechanical polishing (CMP) process.

Afterwards, as shown in FIG. 1H, the dummy gate structure 120 is removed to form a trench 130 in the ILD layer 128, in accordance with some embodiments. The dummy gate dielectric layer 116 and the dummy gate electrode layer 118 are removed by an etching process, such as a dry etching process or a wet etching process.

Next, as shown in FIG. 1I, a gate structure 140 is formed in the trench 130, in accordance with some embodiments. The gate structure 140 includes a gate dielectric layer 134 and a gate electrode layer 138.

The gate dielectric layer 134 may be a single layer or multiple layers. The gate dielectric layer 134 is made of silicon oxide (SiOx), silicon nitride (SixNy), silicon oxynitride (SiON), dielectric material(s) with high dielectric constant (high-k), or a combination thereof. The high dielectric constant (high-k) material may be hafnium oxide (HfO₂), zirconium oxide (ZrO₂), lanthanum oxide (La₂O₃), yttrium oxide (Y₂O₃), aluminum oxide (Al₂O₃), titanium oxide (TiO₂) or another applicable material. In some embodiments, the gate dielectric layer 134 is deposited by a plasma enhanced chemical vapor deposition (PECVD) process or by a spin coating process.

The gate electrode layer 138 is made of conductive material, such as aluminum (Al), copper (Cu), tungsten (W), titanium (Ti), tantalum (Ta), or other applicable materials.

In some embodiments, the gate structure 140 further includes a work function layer. The work function layer is made of metal material, and the metal material may include N-work-function metal or P-work-function metal. The N-work-function metal includes tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal includes titanium nitride (TiN), tungsten nitride (WN), tantalum nitride (TaN), ruthenium (Ru) or a combination thereof.

The gate electrode layer 138 is formed by a deposition process, such as chemical vapor deposition (CVD), physical vapor deposition (PVD), atomic layer deposition (ALD), high density plasma CVD (HDPCVD), metal organic CVD (MOCVD), or plasma enhanced CVD (PECVD).

Next, as shown in FIG. 1J, an etching stop layer 141 is formed over the gate structure 140 and over the ILD layer 128, and a dielectric layer 142 is formed over the etching stop layer 141, in accordance with some embodiments.

The etching stop layer 141 is made of silicon oxide (SiOx), silicon carbide (SiC), silicon nitride (SixNy), silicon carbonitride (SiCN), silicon oxycarbide (SiOC), silicon oxycarbon nitride (SiOCN), or another applicable material. In some embodiments, the etching stop layer 141 is formed by performing a deposition process, such as an atomic layer deposition (ALD) process, a chemical vapor deposition (CVD) process, a physical vapor deposition (PVD) process, or another applicable process.

The dielectric layer 142 may be a single layer or multiple layers. The dielectric layer 142 is made of silicon oxide (SiOx), silicon nitride (SixNy), silicon oxynitride (SiON), dielectric material(s) with low dielectric constant (low-k), or combinations thereof. In some embodiments, the dielectric layer 142 is made of an extreme low-k (ELK) dielectric material with a dielectric constant (k) less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), or porous silicon oxide (SiO₂). In some embodiments, the first dielectric layer 142 is deposited by a plasma enhanced chemical vapor deposition (PECVD) process or by a spin coating process.

Afterwards, as shown in FIG. 1K, a portion of the dielectric layer 142, a portion of the first etching stop layer 141, a portion of the ILD layer 128 are removed to form a trench (not shown), in accordance with some embodiments. Subsequently, a barrier layer 145 is formed in the sidewall surfaces of the trench, and a conductive layer 146 is formed on the barrier layer 145. The barrier layer 145 surrounds the conductive layer 146, and the first dielectric layer 142 surrounds the barrier layer 145. A S/D contact structure is constructed by the barrier layer 145 and the conductive layer 146.

In some embodiments, the barrier layer 145 includes tantalum (Ta), tantalum nitride (TaN), titanium (Ti), titanium nitride (TiN), cobalt tungsten (CoW) or another applicable material. In some embodiments, the barrier layer 145 is formed by a deposition process, such as a chemical vapor deposition (CVD) process, a sputtering process, or another applicable process.

In some embodiments, the conductive layer 146 is made of tungsten (W), ruthenium (Ru), cobalt (Co), copper (Cu), titanium (Ti), molybdenum (Mo), nickel (Ni), tantalum (Ta), or another applicable material. In some embodiments, the conductive material 186 is formed by a deposition process, such as chemical vapor deposition (CVD), physical vapor deposition, (PVD), atomic layer deposition (ALD), or another applicable processes.

After the conductive layer 146 is formed, a polishing process is performed on the barrier layer 145 and the conductive layer 146, until the top surface of the first dielectric layer 142 is exposed. In some embodiments, the polishing process is chemical mechanical polishing (CMP) process. The S/D contact structure 148 is electrically connected to the S/D structure 124. The top surface of the S/D contact structure 148 is higher than the top surface of the gate structure 140.

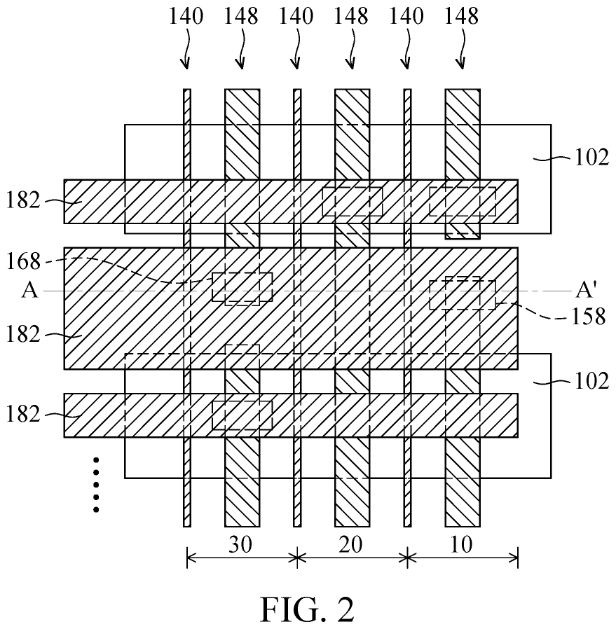

FIG. 2 shows a top view of the semiconductor device structure 100a, in accordance with some embodiments of the disclosure. The substrate 102 has a first region 10, a second region 20 and a third region 30. The second region 20 is between the first region 10 and the third region 30.

The gate structure 140 is formed over the substrate 102, and the S/D contact structure 148 is adjacent to the gate structure 140. A first conductive via 158 is formed in the first region 10 and over the S/D contact structure 148. A second conductive via 168 is formed in the third region 30 and over the S/D contact structure 148. A conductive layer 182 is formed over the first conductive via 158 and the second conductive via 168.

In some embodiments, the first conductive via 158 has a rectangular shape when seen from a top view. In some embodiments, the second conductive via 168 has a rectangular shape when seen from a top view. In some other embodiments, the first conductive via 158 has a circular or other shape when seen from a top view.

It should be noted that the width of the first conductive via 158 is greater than the width of the S/D contact structure 148, and the width of the second conductive via 168 is greater than the width of the S/D contact structure 148. The contact resistance Rc is reduced since the contacting area between the S/D contact structure 148 and the first conductive via 158 is increased. In addition, the sheet resistance Rs between the first conductive via 158 and the conductive layer 182 is reduced since the contacting area between the first conductive via 158 and the conductive layer 182 is increased.

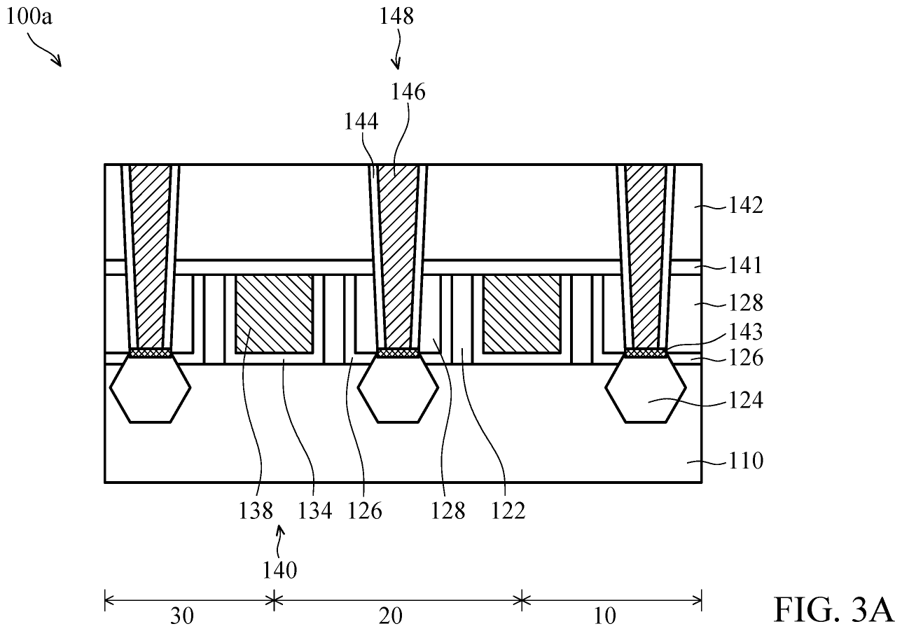

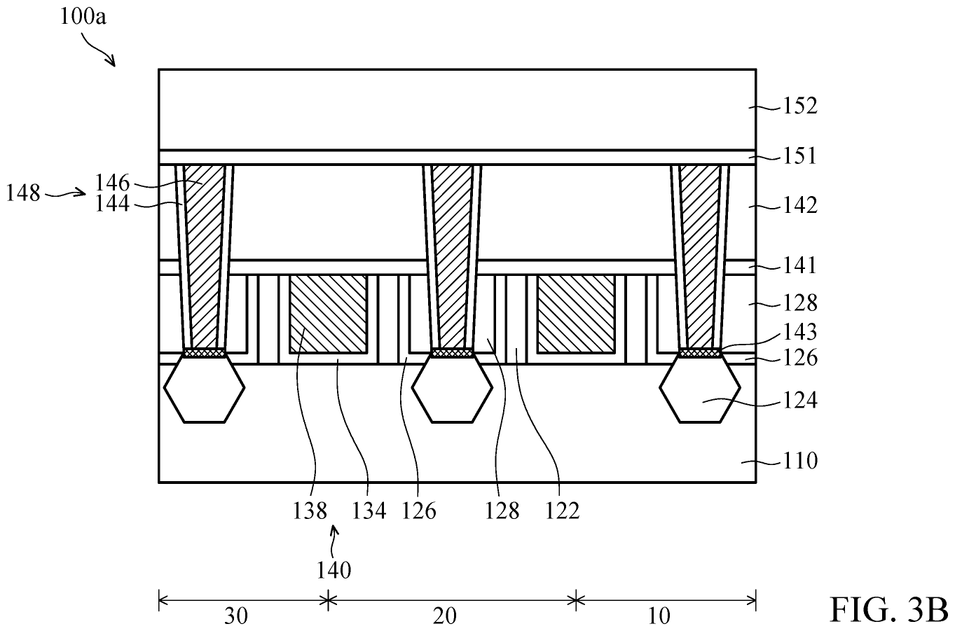

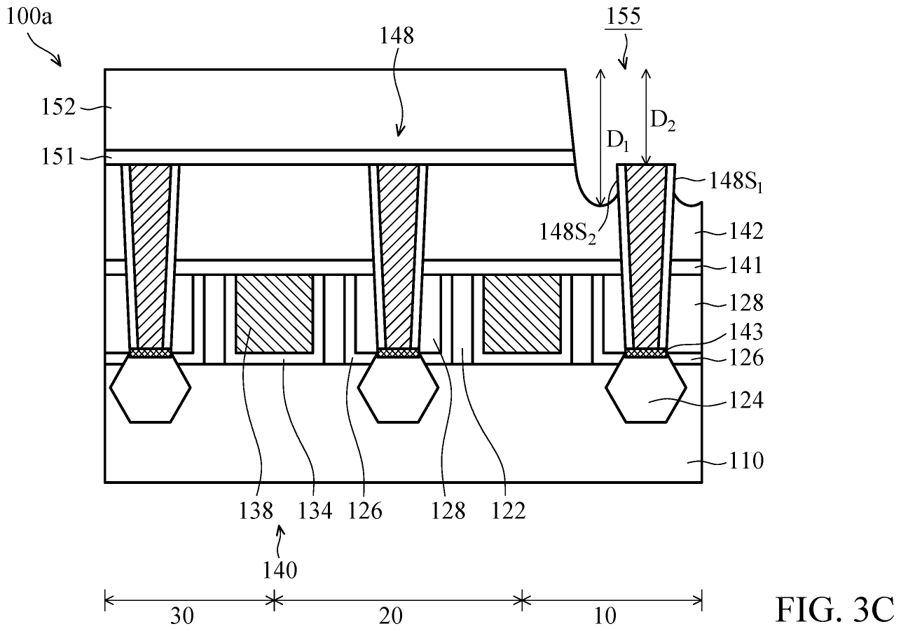

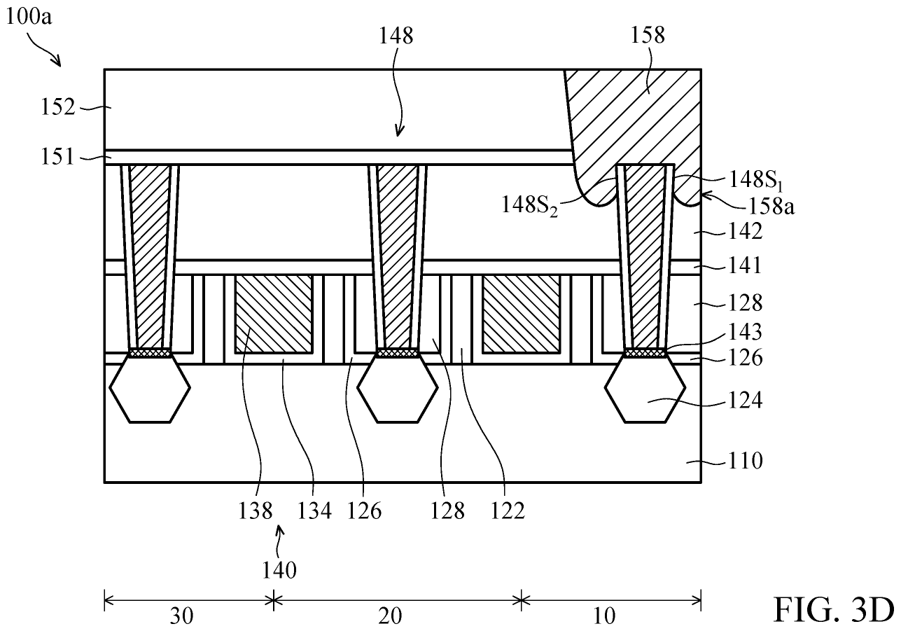

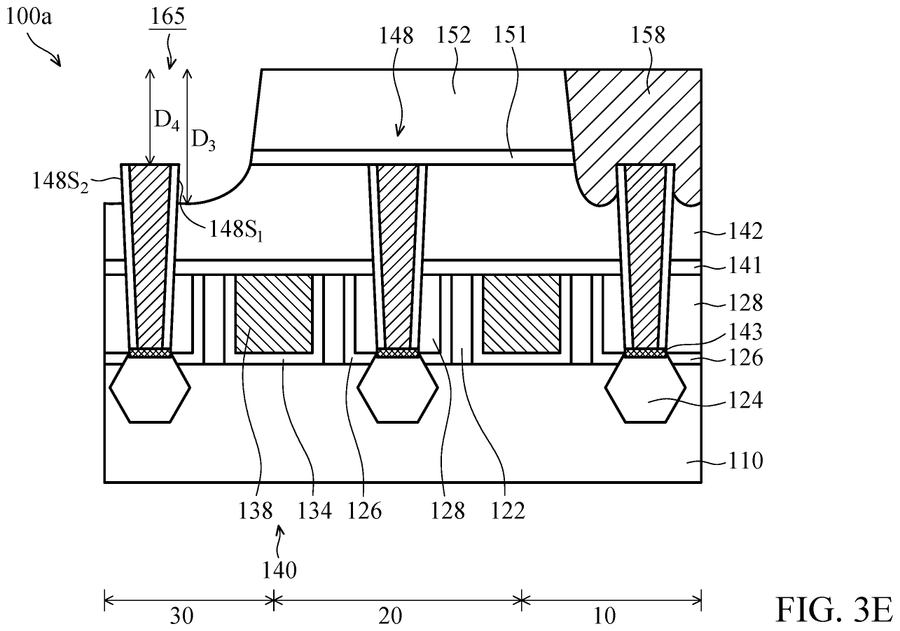

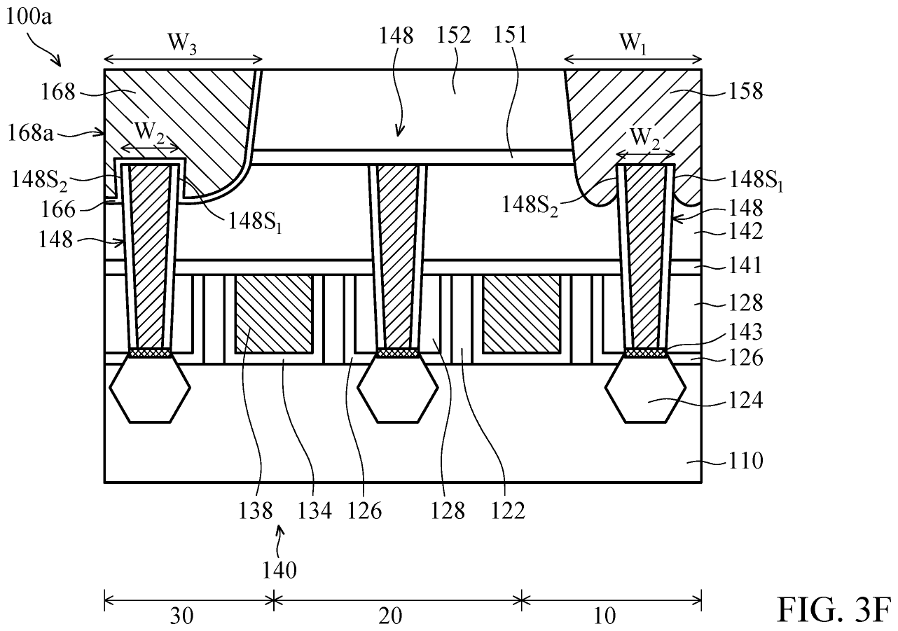

FIG. 3A shows a cross-sectional representation taken along line I-I′ of FIG. 1K. FIG. 3A is a cross-sectional representation taken along line A-A′ of FIG. 2. FIGS. 3B-3F show cross-sectional representations of various stages of forming a semiconductor device structure 100a after the structure of FIG. 3A, in accordance with some embodiments of the disclosure.

As shown in FIG. 3A, a silicide layer 143 is formed on the S/D structure 124, and the S/D contact structure 148 is formed on the silicide layer 143. More specifically, the silicide layer 143 is between the S/D structure 124 and the S/D contact structure 148. The silicide layer 143 is used to reduce contact resistance (Rcsd) between the S/D contact structure 148 and the S/D structure 124. In addition, the S/D contact structure 148 is surrounded by the barrier layer 145.

In some embodiments, the barrier layer 145 is formed over the S/D structure 124, and an annealing process is performed on the metal layer to form the metal silicide layer 143. Firstly, the barrier layer 145 is U-shaped, and the bottom portion of the barrier layer 145 reacts with the S/D structure 124 to form the silicide layer 143. In some other embodiments, the silicide layer 143 is made of titanium silicide (TiSix). In some other embodiments, the silicide layer 143 is made of tantalum silicide (TaSix).

Afterwards, as shown in FIG. 3B, an etching stop layer 151 is formed on the protection layer 150, and a dielectric layer 152 is formed on the etching stop layer 151, in accordance with some embodiments.

Next, as shown in FIG. 3C, a portion of the dielectric layer 152, a portion of etching stop layer 151 is removed, and then a portion of the dielectric layer 142 is removed to form a first trench 155, in accordance with some embodiments. More specifically, the bottommost surface of the first trench 155 is below the bottom surface of the etching stop layer 151 and the bottom surface of the dielectric layer 152. The top surface, the first sidewall 148S₁ of the S/D contact structure 148 and the second sidewall 148S₂ of the S/D contact structure 148 are exposed by the first trench 155. The exposed first sidewall 148S₁and the exposed second sidewall 148S₂ of the S/D contact structure 148 may be symmetric with respect to the S/D contact structure 148.

The first trench 155 has a middle portion and a protruding portion surrounding the middle portion. The bottommost surface of the middle portion is the top surface of the S/D contact structure 148. The protruding portion extends downwardly from the top surface of the dielectric layer 142. The protruding portion of the first trench 155 has a first depth D₁ which is measured from a top surface of the dielectric layer 152 to the bottommost surface of the first trench 155. In some embodiments, the first depth D₁ is in a range from about 20 nm to about 100 nm. The middle portion of the first trench 155 has a second depth D₂ which is measured from a top surface of the dielectric layer 152 to the top surface of the S/D contact structure 148. In some embodiments, the second depth D₂ is in a range from about 20 nm to about 150 nm.

The first trench 155 is formed by an etching process. The etching process includes a multiple etching processes. In some embodiments, the etching process is performed at a pressure in a range from about 15 mTorr to about 450 mTorr. In some embodiments, the etching process is performed at a temperature in a range from about 20 degrees Celsius (° C.) to about 100 degrees Celsius (° C.). In some embodiments, the etching process is performed with power in a range from about 20 W to about 700 W. In some embodiments, the etching process is performed by using H₂, N₂, CxFy, Ar, CHxFy, O₂ or He, or another applicable gas.

Next, as shown in FIG. 3D, a conductive material is filled into the first trench 155 to form a first conductive via 158 in the first region 10, in accordance with some embodiments. The first conductive via 158 in the first region 10 is electrically connected to the S/D structure 124 by the S/D contact structure 148.

The first conductive via 158 has a protruding portion 158a which extends into the dielectric layer 142. In other words, the protruding portion 158a of the first conductive via 158 is embedded in the dielectric layer 142. The protruding portion 158a of the first conductive via 158 is lower than the top surface of the dielectric layer 142. The protruding portion 158a of the first conductive via 158 is lower than the bottom surface of the etching stop layer 151.

The first conductive via 158 includes a conductive material, and the conductive material is in direct contact with the dielectric layer 142 and the dielectric layer 152. It should be noted that no barrier layer or glue layer is between the first conductive via 158 and the dielectric layer 142 and the dielectric layer 152. Furthermore, the first trench 155 can be completely filled with the first conductive via 158 without filled by the barrier layer. Therefore, the resistance of the first conductive via 158 is reduced by filling more conductive material in the first trench 155.

In some embodiments, the first conductive via 158 is made of tungsten (W), ruthenium (Ru), cobalt (Co), copper (Cu), titanium (Ti), molybdenum (Mo), nickel (Ni), tantalum (Ta), or another applicable material. In some embodiments, the first conductive via 158 is formed by a deposition process, such as chemical vapor deposition (CVD), physical vapor deposition, (PVD), atomic layer deposition (ALD), or another applicable processes.

In some embodiments, the first conductive via 158 is formed by a bottom-up deposition process, which is formed form bottom to top. When the first conductive via 158 is formed by the bottom-up deposition process, such as an atomic layer deposition (ALD) process, the first conductive via 158 is formed by performing multiple cycles. Since the first conductive via 158 is formed by several cycles of deposition, the adhesion between the first conductive via 158 and the dielectric layer 142 is improved. Therefore, there is no glue layer or barrier layer between the first conductive via 158 and the dielectric layer 142. In addition, a glue layer has a higher resistance than that of the first conductive via 158. When the first conductive via 158 is in direct contact with the dielectric layer 152 without forming the glue layer or barrier layer, the resistance of the first conductive via 158 is decreased. Therefore, the reliability and the performance of the semiconductor structure 100a are improved.

In some embodiments, the first conductive via 158 is formed by a bottom-up deposition process, such as an atomic layer deposition (ALD) process. In some embodiments, the ALD process is performed at a temperature in a range from about 50 degrees Celsius (° C.) to about 500 degrees Celsius (° C.). In some embodiments, the ALD process is performed with power in a range from about 50 W to about 300 W. In some embodiments, the ALD process is performed at a pressure in a range from about 5 Torr to about 50 Torr.

Afterwards, as shown in FIG. 3E, a portion of the dielectric layer 152, a portion of etching stop layer 151 is removed, and then a portion of the dielectric layer 142 is removed to form a second trench 165, in accordance with some embodiments. More specifically, the bottommost surface of the second trench 165 is below the bottom surface of the etching stop layer 151 and the bottom surface of the dielectric layer 152. The first sidewall 148S1 of the S/D contact structure 148 and the second sidewall 148S2 of the S/D contact structure 148 are exposed by the second trench 165.

The second trench 165 has a middle portion and protruding portion surrounding the middle portion. The bottommost surface of the middle portion is the top surface of the S/D contact structure 148. The protruding portion extends downwardly from the top surface of the dielectric layer 142. The protruding portion of the second trench 165 has a third depth D₃ which is measured from the top surface of the dielectric layer 152 to the bottommost surface of the second trench 165. In some embodiments, the third depth D₃ is in a range from about 20 nm to about 100 nm. The middle portion of the second trench 165 has a fourth depth D₄ which is measured from a top surface of the dielectric layer 152 to the top surface of the S/D contact structure 148. In some embodiments, the fourth depth D₄ is in a range from about 20 nm to about 150 nm.

Next, as shown in FIG. 3F, a barrier layer 166 is formed in the second trench 165, and a second conductive via 168 is formed over the barrier layer 166, in accordance with some embodiments. The barrier layer 166 is configured to reduce the leakage and improve the adhesion between the dielectric layer 152 and the second conductive via 168. The second conductive via 168 in the third region 30 is electrically connected to the S/D structure 124 by the S/D contact structure 148.

In some embodiments, the barrier layer 166 includes tantalum (Ta), tantalum nitride (TaN), titanium (Ti), titanium nitride (TiN), cobalt tungsten (CoW) or another applicable material. In some embodiments, the barrier layer 166 is formed by a deposition process, such as a chemical vapor deposition (CVD) process, a sputtering process, or another applicable process.

In some embodiments, the second conductive via 168 is made of tungsten (W), ruthenium (Ru), cobalt (Co), copper (Cu), titanium (Ti), molybdenum (Mo), nickel (Ni),tantalum (Ta), or another applicable material. In some embodiments, the second conductive via 168 is formed by a deposition process, such as chemical vapor deposition (CVD), physical vapor deposition, (PVD), atomic layer deposition (ALD), or another applicable processes.

As shown in FIG. 3F, the first conductive via 158 is formed in the first region 10, and the second conductive via 168 is formed in the third region 30. The protruding portion of the first conductive via 158 extends downwardly from the top surface of the dielectric layer 142, and the protruding portion of the first conductive via 158 is embedded in the dielectric layer 142. The protruding portion of the second conductive via 168 extends downwardly from the top surface of the dielectric layer 142, and the protruding portion of the second conductive via 168 is embedded in the dielectric layer 142. In other words, a portion of the sidewall of the S/D contact structure 148 is covered by the first conductive via 158 and the second conductive via 168.

The bottommost surface of the first conductive via 158 is lower than the top surface of the S/D contact structure 148. The bottommost surface of the first conductive via 158 is lower than the top surface of the etching stop layer 151. The bottommost surface of the first conductive via 158 is lower than the top surface of the dielectric layer 142.

The protruding portion of the first conductive via 158 has a first protruding portion on and in direct contact with the first sidewall 148S₁ of the S/D contact structure 148 and a second protruding portion on and in direct contact with the second sidewall 148S₂ of the S/D contact structure 148.

The first conductive via 158 has a first width W₁ along the horizontal direction, and the S/D contact structure 148 has a second width W₂ along the horizontal direction. The first width W₁ is greater than the second width W₂. In some embodiments, the first width W₁ is in a range from about 5 nm to about 20 μm.

The second conductive via 168 has a third width W₃ along the horizontal direction. The third width W₃ is greater than the second width W₂. In some embodiments, the third width W₃ is in a range from about 5 nm to about 20 μm.

Since the first conductive via 158 has the protruding portion which cover a portion of the first sidewall S₁ and the second sidewall S₂ of the S/D contact structure 148, the contact area between the S/D contact structure 148 and the first conductive via 158 is increased, and the resistance of the first conductive via 158 is decreased. Therefore, the reliability and the performance of the semiconductor structure 100a are improved.

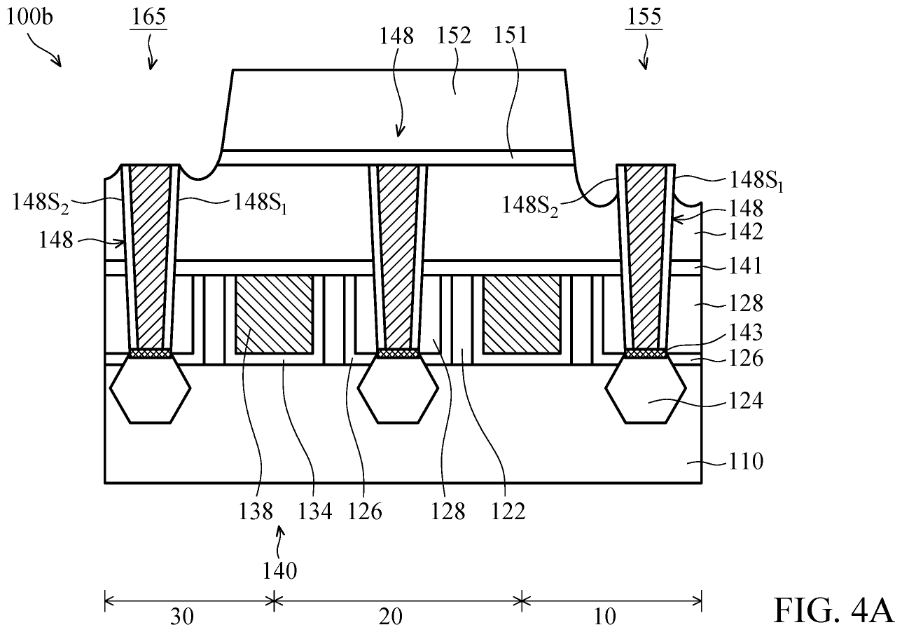

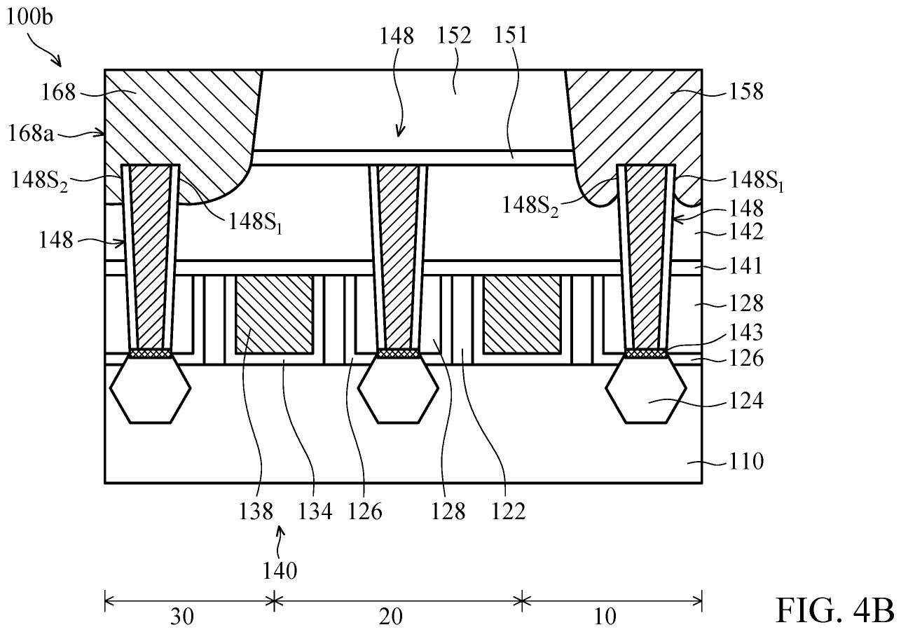

FIGS. 4A-4B show cross-sectional representations of various stages of forming a semiconductor device structure 100b, in accordance with some embodiments of the disclosure. The semiconductor device structure 100b of FIG. 4B includes elements that are similar to, or the same as, elements of the semiconductor device structure 100a of FIG. 3F, the difference between FIG. 4B and FIG. 3F is that no barrier layer is formed between the second conductive via 168 and the dielectric layer 152, the dielectric layer 142 and the S/D contact structure 148.

As shown in FIG. 4A, the first trench 155 and the second trench 165 are simultaneously formed, in accordance with some embodiments of the disclosure. The first trench 155 has the protruding portion lower than the top surface of the dielectric layer 142. The second trench 165 also has the protruding portion lower than the top surface of the dielectric layer 142.

Next, as shown in FIG. 4B, the first conductive via 158 and the second conductive via 168 are simultaneously formed, in accordance with some embodiments of the disclosure. It should be noted that the first conductive via 158 and the second conductive via 168 are formed by the bottom-up deposition process, such as ALD process. Since the adhesion between the first conductive via 158 and the second conductive via 168 and the dielectric layer 152 is improved by using the bottom-up process for forming the first conductive via 158 and the second conductive via 168, no barrier layer is formed between the first conductive via 158 and the dielectric layer 152, and between the second conductive via 168 and the dielectric layer 152.

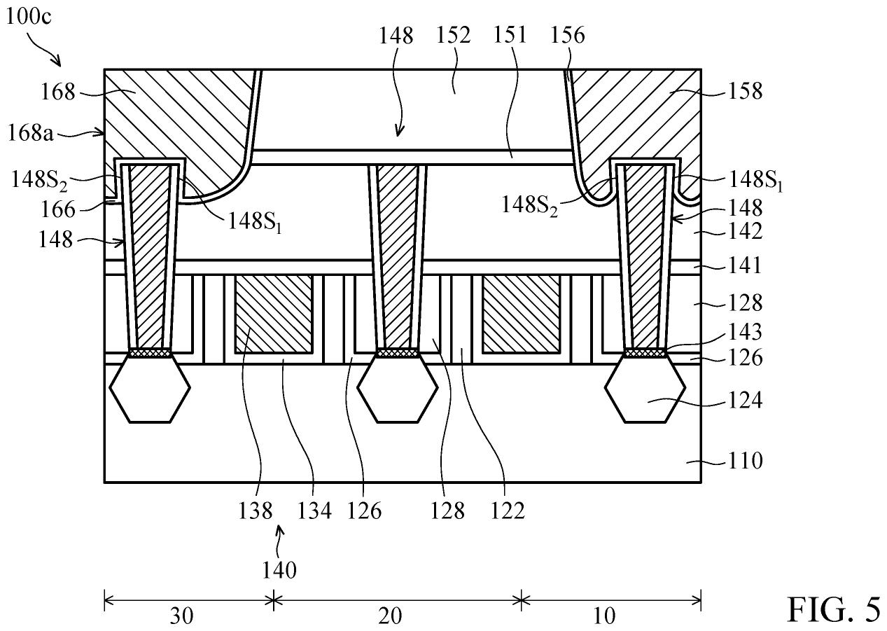

FIG. 5 shows a cross-sectional representation of a semiconductor device structure 100c, in accordance with some embodiments of the disclosure. The semiconductor device structure 100c of FIG. 5 includes elements that are similar to, or the same as, elements of the semiconductor device structure 100b of FIG. 4B, the difference between FIG. 5 and FIG. 4B is that, a barrier layer 156 is between the first conductive via 158 and the dielectric layer 152. The barrier layer 156 can reduce the leakage when the first conductive via 158 is close to adjacent conductive structure.

In some embodiments, the barrier layer 156 includes tantalum (Ta), tantalum nitride (TaN), titanium (Ti), titanium nitride (TiN), cobalt tungsten (CoW) or another applicable material. In some embodiments, the barrier layer 156 is formed by a deposition process, such as a chemical vapor deposition (CVD) process, a sputtering process, or another applicable process.

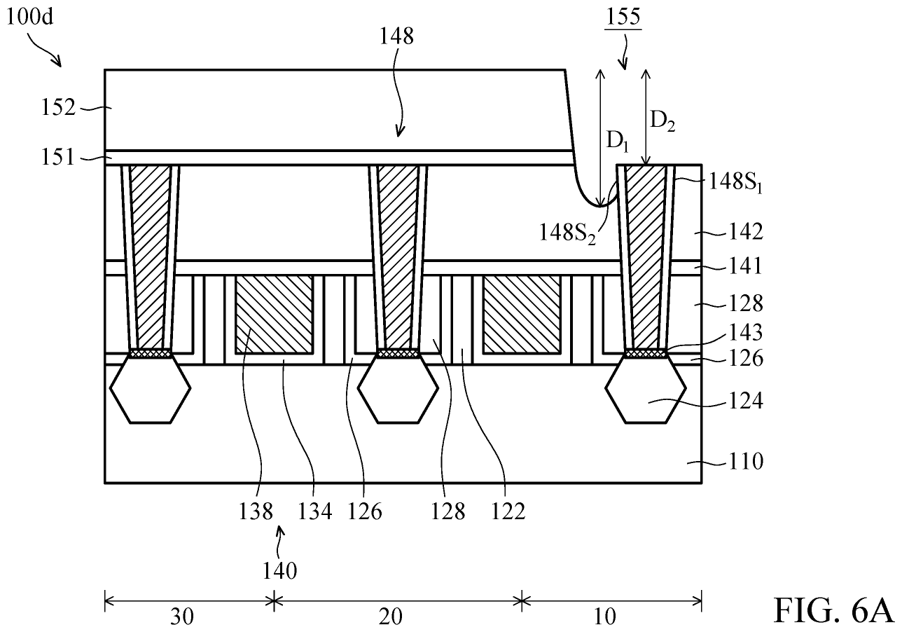

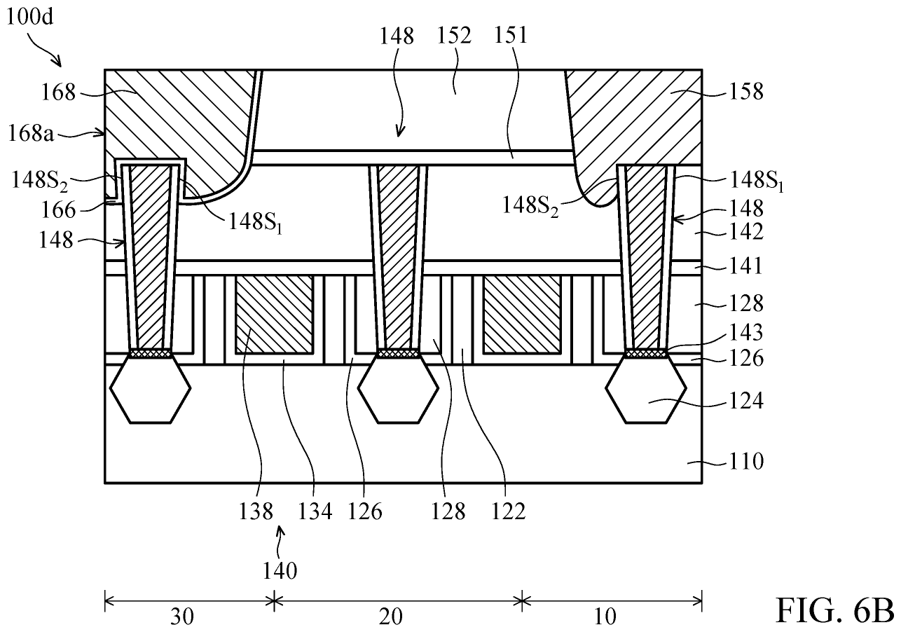

FIGS. 6A-6B show cross-sectional representations of various stages of forming a semiconductor device structure 100d, in accordance with some embodiments of the disclosure. The semiconductor device structure 100d of FIG. 6B includes elements that are similar to, or the same as, elements of the semiconductor device structure 100a of FIG. 3F, the difference between FIG. 6B and FIG. 3F is that, the first conductive via 158 in FIG. 6B has a different profile from that of the first conductive via in FIG. 3F.

As shown in FIG. 6A, the first sidewall 148S₁ of the S/D contact structure 148 is not exposed by the first trench 155, and the second sidewall 148S₂ of the S/D contact structure 148 is exposed by the first trench 155, in accordance with some embodiments of the disclosure. The first trench 155 has protruding portion at the second sidewall 148S₂.

Afterwards, as shown in FIG. 6B, the first conductive via 158 is formed in the first trench 155, and the second conductive via 168 is adjacent to the first conductive via 158, in accordance with some embodiments of the disclosure.

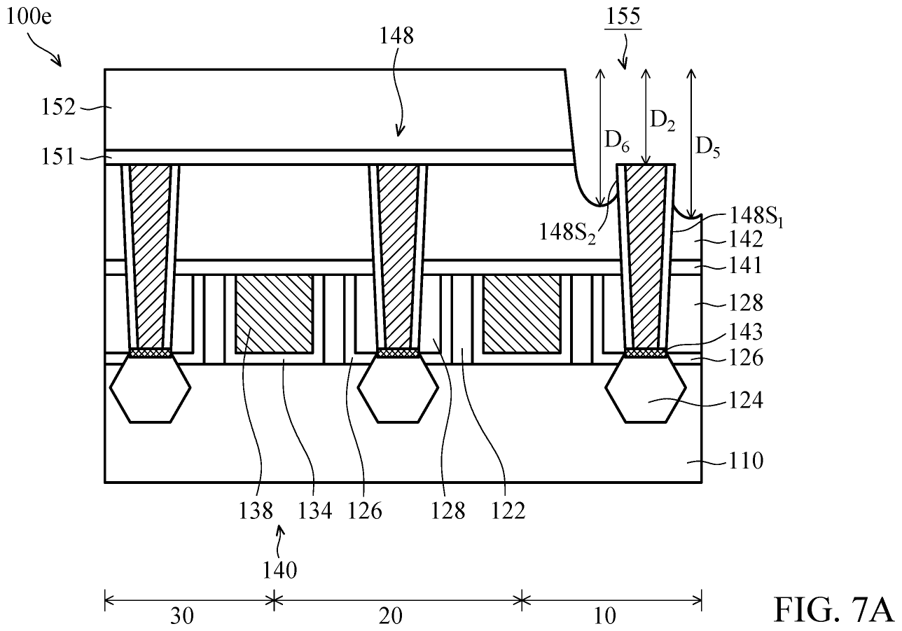

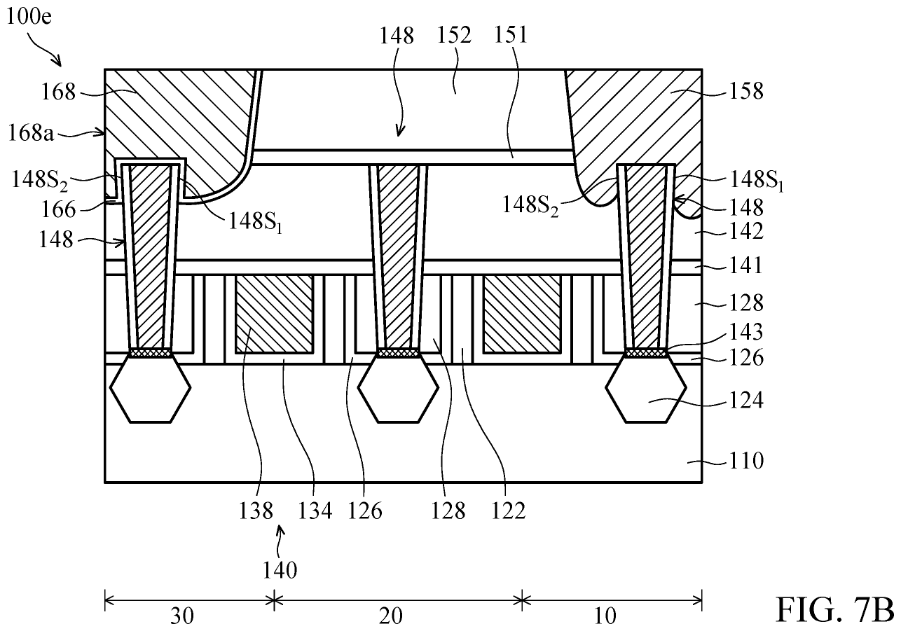

FIGS. 7A-7B show cross-sectional representations of various stages of forming a semiconductor device structure 100e, in accordance with some embodiments of the disclosure. The semiconductor device structure 100e of FIG. 7B includes elements that are similar to, or the same as, elements of the semiconductor device structure 100a of FIG. 3F, the difference between FIG. 7B and FIG. 3F is that, the first conductive via 158 in FIG. 7B has a different profile from that of the first conductive via in FIG. 3F.

As shown in FIG. 7A, the first sidewall 148S₁ and the second sidewall 148S₂ of the S/D contact structure 148 are exposed by the first trench 155, in accordance with some embodiments of the disclosure. More specifically, the exposed portion of the first sidewall 148S₁ is more than the exposed portion of the second sidewall 148S₂ of the S/D contact structure 148.

In some embodiments, the first trench 155 has a first protruding portion on the first sidewall 148S₁ which has a fifth depth D₅. The fifth depth D₅ is measured from a top surface of the dielectric layer 152 to the bottommost surface of the first protruding portion of the first trench 155. In some embodiments, the first trench 155 has a second protruding portion on the second sidewall 148S₂ which has a sixth depth D₆. The middle portion of the first trench 155 has the second depth Da which is measured from a top surface of the dielectric layer 152 to the top surface of the S/D contact structure 148. The fifth D₅ is greater than the sixth depth D₆. In addition, the sixth depth D₆ is greater than the second depth D₂.

Afterwards, as shown in FIG. 7B, the first conductive via 158 is formed in the first trench 155, and the second conductive via 168 is adjacent to the first conductive via 158, in accordance with some embodiments of the disclosure. The protruding portion of the first conductive via 158 has the first protruding portion and the second protruding portion, and the height of the first portion is greater than the height of the second portion. The bottom surface of the first protruding portion is lower than the bottom surface of the second protruding portion of the first conductive via 158.

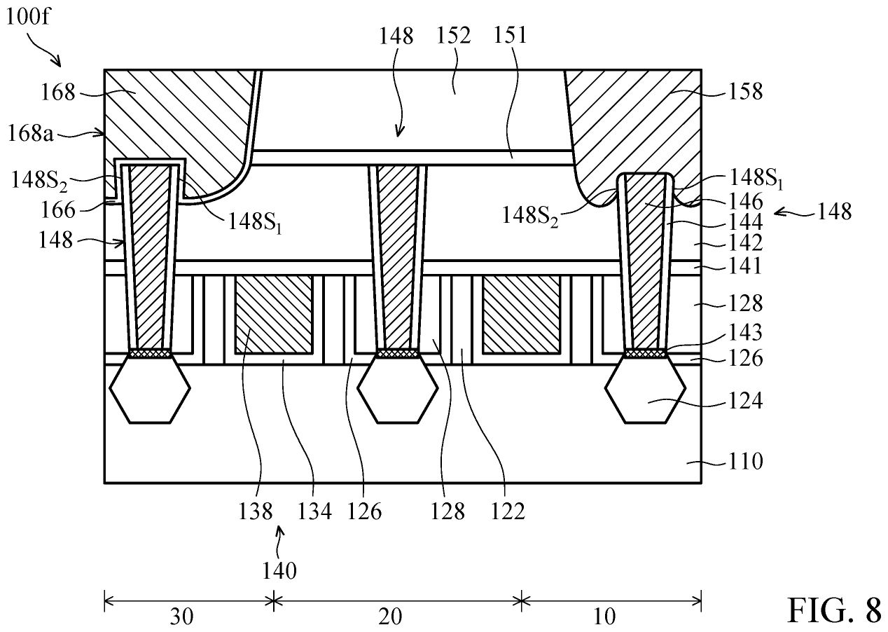

FIG. 8 shows a cross-sectional representation of a semiconductor device structure 100f, in accordance with some embodiments of the disclosure. The semiconductor device structure 100f of FIG. 8 includes elements that are similar to, or the same as, elements of the semiconductor device structure 100a of FIG. 3F, the difference between FIG. 8 and FIG. 3F is that, a portion of the S/D contact structure 148 is removed when forming the first trench 155, and therefore the S/D contact structure 148 has a rounded top surface.

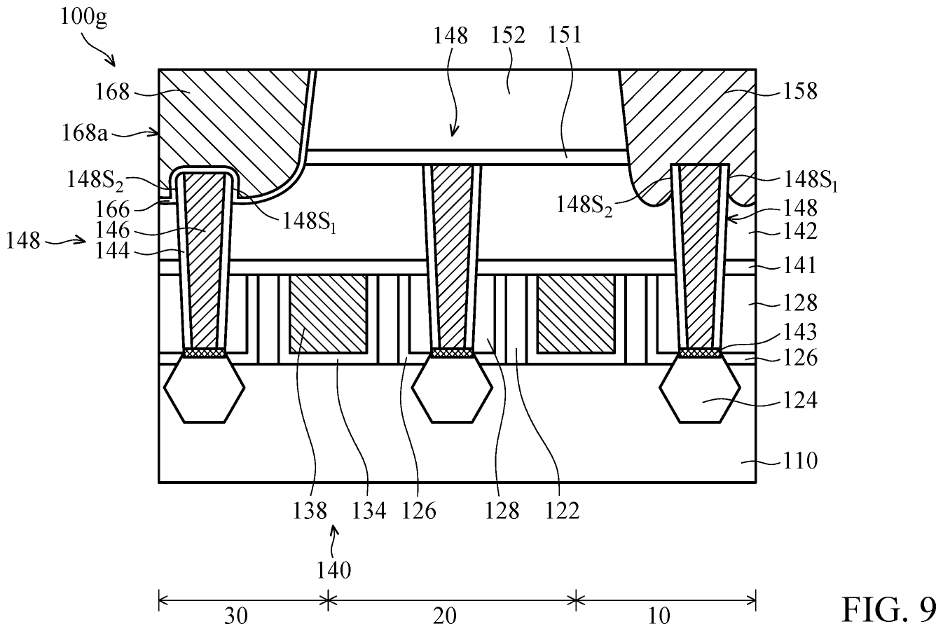

FIG. 9 shows a cross-sectional representation of a semiconductor device structure 100g, in accordance with some embodiments of the disclosure. The semiconductor device structure 100g of FIG. 9 includes elements that are similar to, or the same as, elements of the semiconductor device structure 100a of FIG. 3F, the difference between FIG. 9 and FIG. 3F is that, a portion of the S/D contact structure 148 is removed when forming the second trench 165, and therefore the S/D contact structure 148 has a rounded top surface.

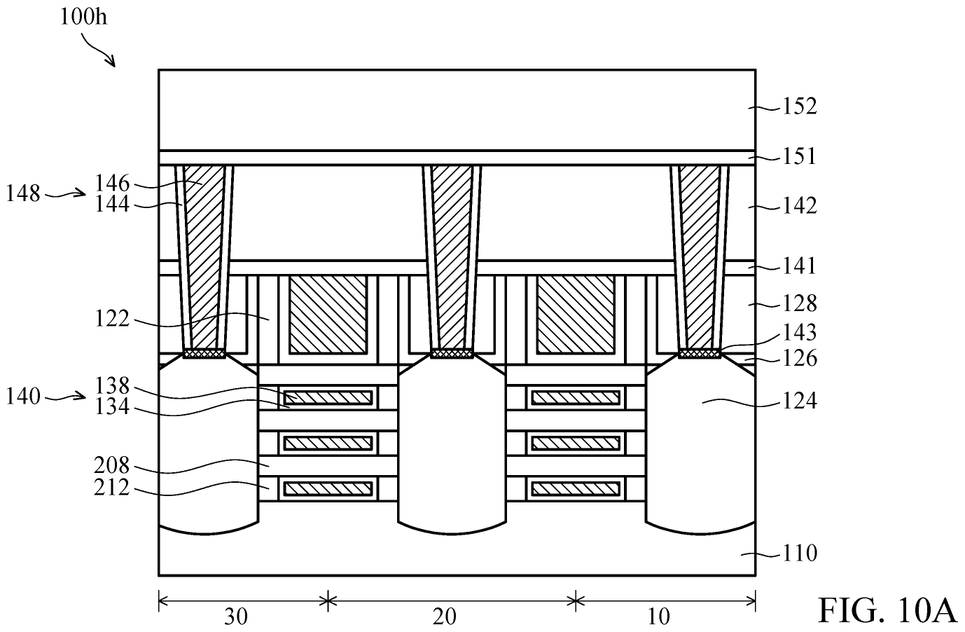

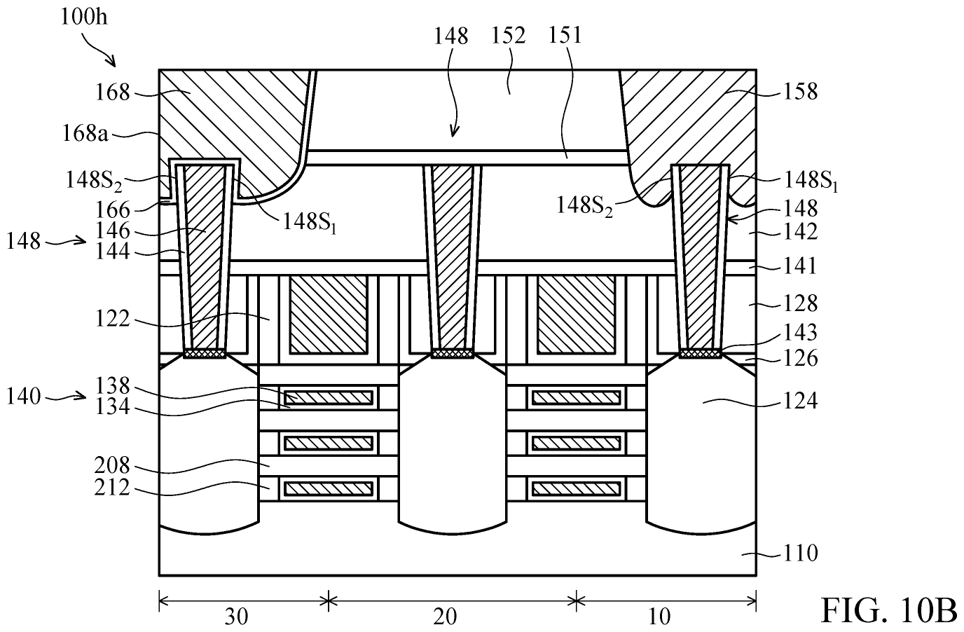

FIGS. 10A-10B show cross-sectional representations of various stages of forming a semiconductor device structure 100h, in accordance with some embodiments of the disclosure. The semiconductor device structure 100h of FIG. 10B includes elements that are similar to, or the same as, elements of the semiconductor device structure 100a of FIG. 3F, the difference between FIG. 10B and FIG. 3F is that, the semiconductor device structure 100h is a gate all around (GAA) transistor structure, in accordance with some embodiments of the disclosure.

As shown in FIG. 10A, the fin structure 110 includes a number of nanostructures 208, and the nanostructures 208 are surrounded by the gate structure 140.

The inner spacers 212 are between the gate structure 140 and the S/D structure 124. The inner spacers 212 may be configured to separate the S/D structure 124 and the gate structure 140. In some embodiments, the inner spacers 212 have curved sidewalls. In some embodiments, the inner spacers 212 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacers 212 are formed by a deposition process, such as chemical vapor deposition (CVD), physical vapor deposition, (PVD), atomic layer deposition (ALD), or another applicable processes.

A semiconductor stack, including first semiconductor material layers (not shown) and second semiconductor material layers 208, is formed over the substrate 102. The first semiconductor material layers and the second semiconductor material layers 208 are alternately stacked over the substrate 102 to form the semiconductor stack. In some embodiment, the first semiconductor material layers and the second semiconductor material layers 208 are made of different semiconductor materials. In some embodiments, the first semiconductor material layers are made of SiGe, and the second semiconductor material layers 208 are made of silicon. The dummy gate structure (not shown) is formed over the semiconductor stack, and the S/D structure is formed adjacent to the dummy gate structure. The etching stop layer and the ILD is formed over the dummy gate structure and the S/D structure, and then the dummy gate structure is removed. Next, the first semiconductor material layers are removed to form a trench and form the second semiconductor material layers 208 (or the nanostructures 208). The gate structure 140 is filled into the trench, and the second semiconductor material layers 208 (or the nanostructures 208) are surrounded by the gate structure 140.

Afterwards, as shown in FIG. 10B, the first conductive via 158 is formed in the first region 10, and the second conductive via 168 is adjacent to the first conductive via 158, in accordance with some embodiments of the disclosure.

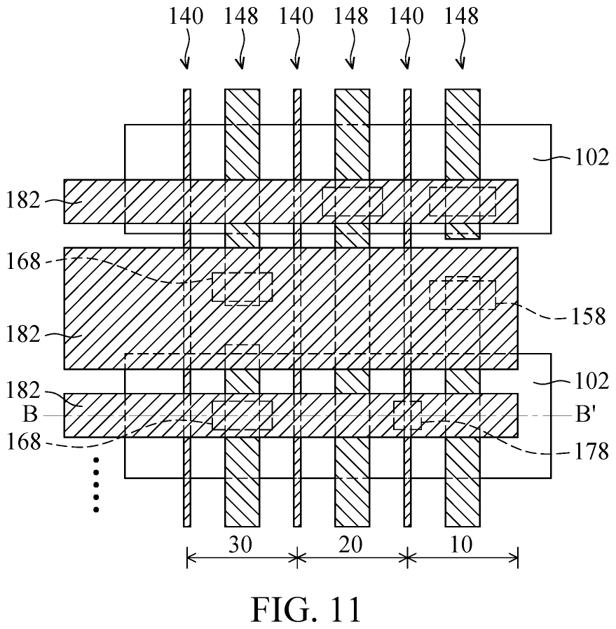

FIG. 11 shows a top view of a semiconductor device structure 100i, in accordance with some embodiments of the disclosure.

As shown in FIG. 11, a third conductive via 178 is directly over the gate structure 140, in accordance with some embodiments of the disclosure. The third conductive layer 178 is directly over the gate structure 140, and between the first conductive via 158 and the second conductive via 168.

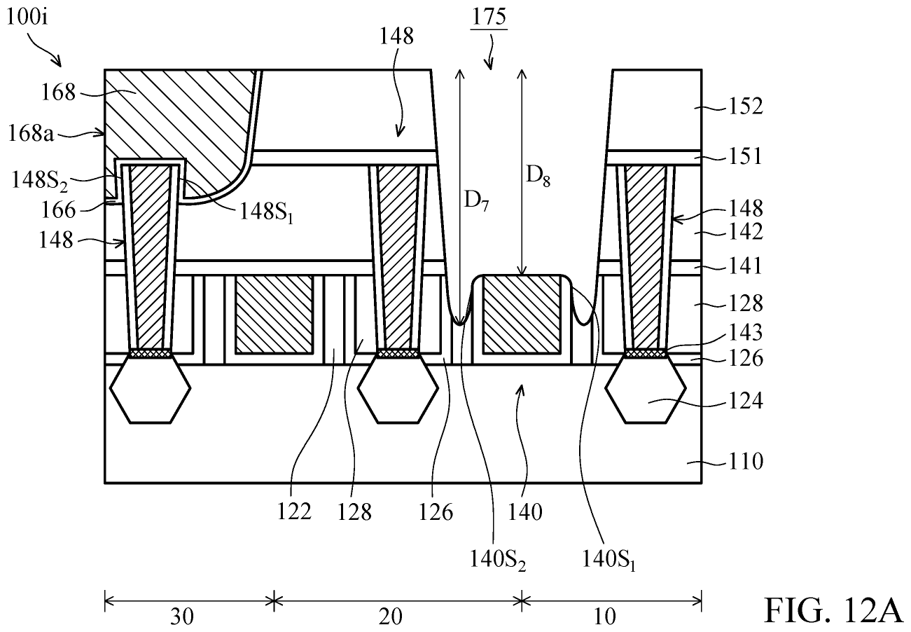

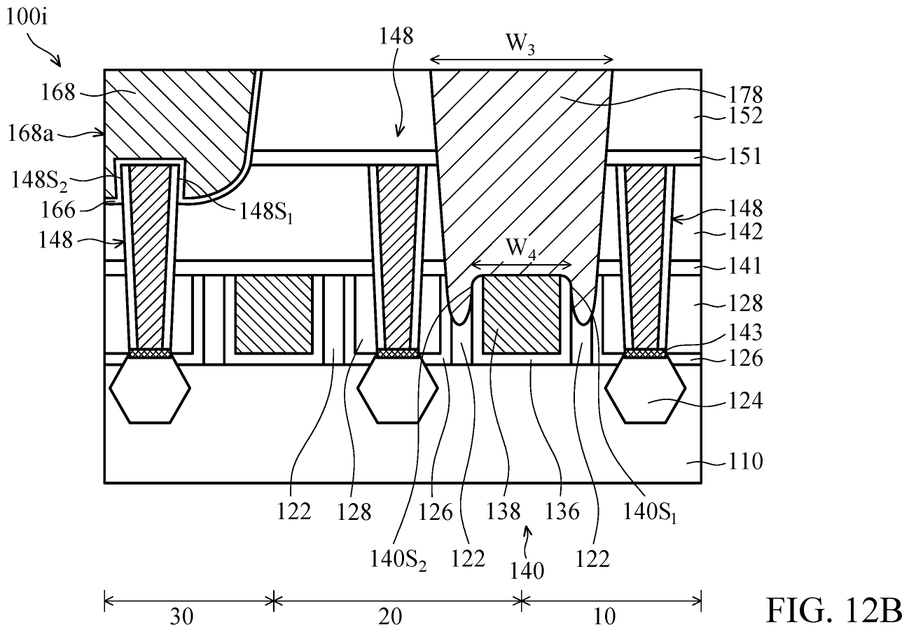

FIGS. 12A-12B show cross-sectional representations of various stages of forming the semiconductor device structure 100i, in accordance with some embodiments of the disclosure. FIG. 12B is a cross-sectional representation taken along line B-B′ of FIG. 11.

As shown in FIG. 12A, a third trench 175 is formed over the gate structure 140, in accordance with some embodiments of the disclosure. More specifically, the bottommost surface of the third trench 175 is below the bottom surface of the etching stop layer 141 and the bottom surface of the dielectric layer 142. The top surface, the first sidewall 140S₁ of the gate structure 140 and the second sidewall 140S₂ of the gate structure 140 are exposed by the third trench 175. The exposed first sidewall 140S₁and the exposed second sidewall 140S₂ of the gate structure 140 may be symmetric with respect to the gate structure 140.

The third trench 175 has a middle portion and a protruding portion surrounding the middle portion. The bottommost surface of the middle portion is the top surface of the gate structure 140. The protruding portion extends downwardly from the top surface of the ILD layer 128. The protruding portion of the third trench 175 has a seventh depth D₇ which is measured from a top surface of the dielectric layer 152 to the bottommost surface of the third trench 175. In some embodiments, the seventh depth D₇ is in a range from about 5 nm to about 100 nm. The middle portion of the third trench 175 has an eighth depth D₈ which is measured from a top surface of the dielectric layer 152 to the top surface of the gate structure 140. In some embodiments, the eighth depth D₈ is in a range from about 5 nm to about 150 nm.

The third trench 175 is formed using an etching process. The etching process includes a number of etching processes. In some embodiments, the etching process is performed at a pressure in a range from about 15 mT to about 450 mT. In some embodiments, the etching process is performed at a temperature in a range from about 20 degrees Celsius (° C.) to about 100 degrees Celsius (° C.). In some embodiments, the etching process is performed with power in a range from about 20 W to about 700 W. In some embodiments, the etching process is performed by using H₂, N₂, CxFy, Ar, CHxFy, O₂ or He, or another applicable gas.

Next, as shown in FIG. 12B, a third conductive via 178 is formed over the gate structure 140, in accordance with some embodiments of the disclosure. The third conducive via 178 is electrically connected to the gate structure 140. The third conductive via 178 is directly over the gate structure 140 and between the first conductive via 158 and the second conductive via 168. In addition, the protruding portion of the third conductive via 178 extends downwardly from the top surface of the gate structure 140. The protruding portion of the third conductive via 178 is lower than the top surface of the gate structure 140.

The bottommost surface of the third conductive via 178 is lower than the top surface of the gate structure 140. The bottommost surface of the third conductive via 178 is lower than the top surface of the etching stop layer 141. The bottommost surface of the third conductive via 178 is lower than the top surface of the dielectric layer 142.

A portion of the gate structure 140 is covered by the third conductive via 178. The third conductive via 178 is in direct contact with the top surface and the sidewalls of the gate structure 140. The protruding portion of the third conductive via 178 has a first protruding portion on and in direct contact with the first sidewall 140S₁ of the gate structure 140 and a second protruding portion on and in direct contact with the second sidewall 140S₂ of the gate structure 140. The third conductive via 178 is in direct contact with the gate spacer 122. The bottommost surface of the third conductive via 178 is in direct contact with the topmost surface of the gate spacer 122. In some other embodiments, a barrier layer (not shown) is between the third conducive via 178 and the gate structure 140.

The top surface of the third conductive via 178 has a third width W₃ along the horizontal direction, and the gate structure 140 has a fourth width W₄ along the horizontal direction. The third width W₃ is greater than the fourth width W₄.

In some embodiments, the third conductive via 178 is made of tungsten (W), ruthenium (Ru), cobalt (Co), copper (Cu), titanium (Ti), molybdenum (Mo), nickel (Ni),tantalum (Ta), or another applicable material. In some embodiments, the third conductive via 178 is formed by a deposition process, such as chemical vapor deposition (CVD), physical vapor deposition, (PVD), atomic layer deposition (ALD), or another applicable processes.

In some embodiments, the third conductive via 178 is formed by a bottom-up deposition process, which is formed form bottom to top. When the third conductive via 178 is formed by the bottom-up deposition process, which may be an atomic layer deposition (ALD) process, the third conductive via 178 is formed by performing multiple cycles. Since the third conductive via 178 is formed by several cycles of deposition, the adhesion between the third conductive via 178 and the dielectric layer 142 and the ILD layer 128 is improved. Therefore, there is no glue layer or barrier layer between the third conductive via 158 and the dielectric layer 142. In addition, a glue layer has a higher resistance than that of the third conductive via 178. When the third conductive via 178 is in direct contact with the dielectric layer 142 without forming the glue layer or barrier layer, the resistance of the third conductive via 178 is decreased. Therefore, the reliability and the performance of the semiconductor structure 100i are improved.

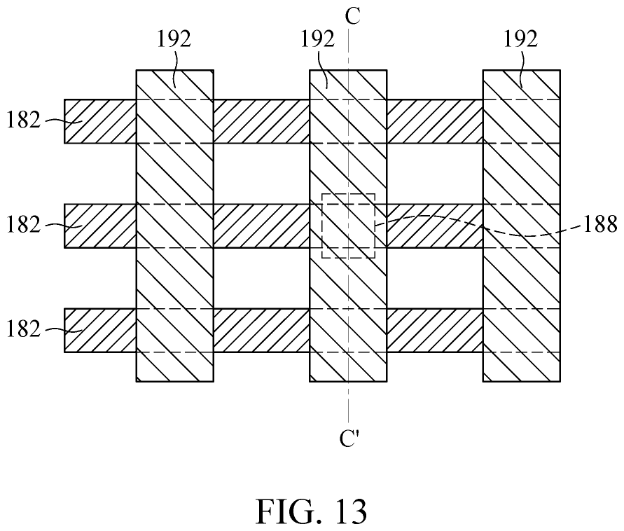

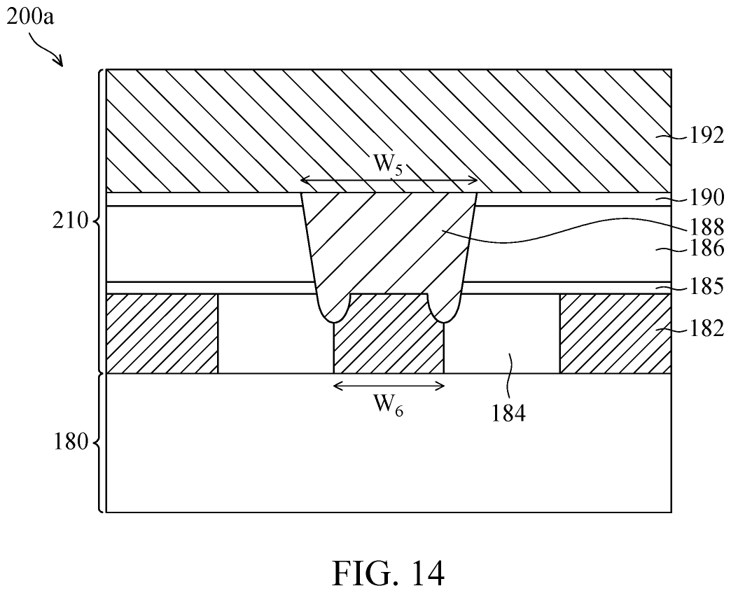

FIG. 13 shows a top view of the semiconductor device structure 200a, in accordance with some embodiments of the disclosure. FIG. 14 shows a cross-sectional representation taken along line C-C′ of FIG. 13.

As shown in FIGS. 13 and 14, a substrate structure 180 is formed, and an interconnect structure 210 is formed over the substrate structure 180, in accordance with some embodiments of the disclosure. The substrate structure 180 may include the semiconductor device structures 100a, 100b, 100c, 100d, 100e, 100f, 100g, 100h, 100i as mentioned above. The interconnect structure 210 includes the conductive layers embedded in the dielectric layers.

A first conductive layer 182 is formed in a dielectric layer 184, and an etching stop layer 185 is formed over the first conductive layer 182 and the dielectric layer 184. A fourth conducive via 188 is formed over the first conductive layer 182. A dielectric layer 186 is formed over the etching stop layer 185, and an etching stop layer 190 is formed over the dielectric layer 186. A conductive layer 192 is formed over the etching stop layer 190.

In some embodiments, the fourth conducive via 188 is directly over the S/D contact structure 148 or directly over the gate structure 140. The fourth conducive via 188 is through the etching stop layer 190, the dielectric layer 186, the etching stop layer 185 and the dielectric layer 184. The fourth conducive via 188 has protruding portion extends downwardly from the top surface of the conductive layer 182. The fourth conducive via 188 has protruding portion lower than the top surface of the conductive layer 182. The fourth conducive via 188 is in direct contact with the top surface and sidewalls of the conductive layer 182. In addition, the bottommost surface of the fourth conducive via 188 is lower than the top surface of the conductive layer 182. In some other embodiments, a barrier layer (not shown) is between the fourth conducive via 188 and the conductive layer 182.

In some embodiments, the conductive layers 182, 192 are made of tungsten (W), ruthenium (Ru), cobalt (Co), copper (Cu), titanium (Ti), molybdenum (Mo), nickel (Ni),tantalum (Ta), or another applicable material. In some embodiments, the conductive layers 182, 192 are formed by a deposition process, such as chemical vapor deposition (CVD), physical vapor deposition, (PVD), atomic layer deposition (ALD), or another applicable processes.

In some embodiments, the fourth conductive via 188 is made of tungsten (W), ruthenium (Ru), cobalt (Co), copper (Cu), titanium (Ti), molybdenum (Mo), nickel (Ni),tantalum (Ta), or another applicable material. In some embodiments, the fourth conductive via 188 is formed by a deposition process, such as chemical vapor deposition (CVD), physical vapor deposition, (PVD), atomic layer deposition (ALD), or another applicable processes.

The top surface of the fourth conductive via 188 has a fifth width W₅ along the horizontal direction, and the conductive layer 82 has a sixth width W₆ along the horizontal direction. The fifth width W₅ is greater than the sixth width W₆.

Each of the first conductive via 158, the second conducive via 168, the third conductive via 178 and the fourth conductive via 188 respectively has the protruding portion. The protruding portion increase the contact area of the conductive via, and therefore the resistances of the first conductive via 158, the second conducive via 168, the third conductive via 178 and the fourth conductive via 188 is decreased. Therefore, the reliability and the performance of the semiconductor structure 100a/100b/100c/100d/100f/100g/100h/100i are improved. In addition, when the first conductive via 158, the second conducive via 168, the third conductive via 178 and the fourth conductive via 188 are formed by bottom-up deposition process, no barrier layer or glue layer is formed before forming the conducive vias. Therefore, the resistance of the first conductive via 158, the second conducive via 168, the third conductive via 178 and the fourth conductive via 188 is reduced by filling more conductive material in the trenches 155, 165, 175.

Also, while the disclosed methods are illustrated and described below as a series of acts or events, it should be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming a semiconductor device structure and method for formation the same are provided. The semiconductor device structure includes a fin structure formed over a substrate, and a gate structure formed over the fin structure. A first dielectric layer formed over the gate structure, and a second dielectric layer formed over the second dielectric layer. An S/D structure is formed adjacent to the gate structure, and an S/D contact structure is formed on the S/D structure and in the first dielectric layer. A trench is formed through the second dielectric layer and extends into the first dielectric layer, and a conductive via is formed in the trench. The conductive via has a protruding portion extends into the first dielectric layer. In some embodiments, the conductive via is directly over the S/D contact structure or the gate structure. In some other embodiments, the conductive via is formed in an interconnect structure above the gate structure and the S/D contact structure. The protruding portion increases the contact area between the conductive via and the first dielectric layer and the second dielectric layer, and therefore the resistance of the conductive via is decreased. Therefore, the reliability and the performance of the semiconductor structure are improved.

In some embodiments, a semiconductor device structure is provided. The semiconductor device structure includes a fin structure formed over a substrate, and a gate structure formed over the fin structure. The semiconductor device structure includes a source/drain (S/D) structure formed over the fin structure and adjacent to the gate structure, and a first dielectric layer formed over the gate structure and the S/D structure. The semiconductor device structure further includes an S/D contact structure formed in the first dielectric layer over the S/D structure, and a second dielectric layer formed over the S/D contact structure. The semiconductor device structure includes a first conductive via formed in the second dielectric layer, and the first conductive via is directly over the S/D contact structure or directly over the gate structure. The first conductive via has a protruding portion lower than the top surface of the S/D contact structure or lower than the top surface of the gate structure.

In some embodiments, a semiconductor device structure is provided. The semiconductor device structure includes a gate structure formed over a substrate, and a source/drain (S/D) structure formed adjacent to the gate structure. The semiconductor device structure includes a first dielectric layer formed over the gate structure and the S/D structure, and an S/D contact structure formed in the first dielectric layer over the S/D structure. The semiconductor device structure includes a second dielectric layer formed over the S/D contact structure, and a first conductive via formed in the second dielectric and over the S/D contact structure. The first conductive via has a protruding portion embedded in the first dielectric layer. The semiconductor device structure includes a second conductive via adjacent to the first conductive via, and the second conductive via has a protruding portion embedded in the first dielectric layer.

In some embodiments, a method for forming a FinFET device structure is provided. The method includes forming a gate structure over a substrate, and forming a source/drain (S/D) structure adjacent to the gate structure. The method includes forming a first dielectric layer over the gate structure and the S/D structure, and forming an S/D contact structure in the first dielectric layer over the S/D structure. The method includes forming a second dielectric layer over the first dielectric layer, and removing a portion of the second dielectric layer and a portion of the first dielectric layer to form a first trench. The first trench extends into the first dielectric layer, and a top surface and a sidewall surface of the S/D contact structure are exposed. The method includes forming a first conductive via in the first trench, and the first conductive via has a protruding portion embedded in the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a fin structure formed over a substrate;
a gate structure formed over the fin structure;
a source/drain (S/D) structure formed over the fin structure and adjacent to the gate structure;
a first dielectric layer formed over the gate structure and the S/D structure;
an S/D contact structure formed in the first dielectric layer over the S/D structure;
a second dielectric layer formed over the S/D contact structure; and
a first conductive via formed in the second dielectric layer, wherein the first conductive via is directly over the S/D contact structure or directly over the gate structure, and the first conductive via has a protruding portion that is lower than a top surface of the S/D contact structure or lower than a top surface of the gate structure.

2. The semiconductor device structure as claimed in claim 1, further comprising:
an etching stop layer between the first dielectric layer and the second dielectric layer, wherein the protruding portion of the first conductive via is lower than a bottom surface of the etching stop layer.

3. The semiconductor device structure as claimed in claim 1, wherein the first conductive via comprises a first conductive material, and the first conductive material is in direct contact with the first dielectric layer and the second dielectric layer.

4. The semiconductor device structure as claimed in claim 1, further comprising:
a gate spacer formed adjacent to the gate structure, wherein the protruding portion of the first conductive via is in direct contact with the gate spacer.

5. The semiconductor device structure as claimed in claim 1, further comprising:
a conductive layer formed over the second dielectric layer; and
a second conductive via formed over the conductive layer, wherein the second conductive via has a protruding portion that is lower than a top surface of the conductive layer.

6. The semiconductor device structure as claimed in claim 1, wherein the fin structure comprises a plurality of nanostructures.

7. The semiconductor device structure as claimed in claim 1, wherein the first conductive via has a first width along a horizontal direction, and the S/D contact structure has a second width along the horizontal direction, and the first width is greater than the second width.

8. The semiconductor device structure as claimed in claim 1, wherein the protruding portion of the first conductive via comprises a first portion and a second portion, the first portion is in direct contact with a first sidewall of the S/D structure, and the second portion is in direct contact with a second sidewall of the S/D structure.

9. The semiconductor device structure as claimed in claim 8, wherein a bottom surface of the first portion of the protruding portion of the first conductive via is lower than a bottom surface of the second portion of the protruding portion of the first conductive via. The semiconductor device structure as claimed in claim 1, wherein the first conductive via is in direct contact with a top surface of the gate structure and a sidewall of the gate structure.

11. A semiconductor device structure, comprising:
a gate structure formed over a substrate;
a source/drain (S/D) structure formed adjacent to the gate structure;
a first dielectric layer formed over the gate structure and the S/D structure;
an S/D contact structure formed in the first dielectric layer over the S/D structure;
a second dielectric layer formed over the S/D contact structure; and
a first conductive via formed in the second dielectric and over the S/D contact structure, wherein the first conductive via has a protruding portion embedded in the first dielectric layer; and
a second conductive via adjacent to the first conductive via, wherein the second conductive via has a protruding portion embedded in the first dielectric layer.

12. The semiconductor device structure as claimed in claim 11, wherein a bottommost surface of the first conductive via is lower than a top surface of the S/D contact structure.

13. The semiconductor device structure as claimed in claim 11, wherein a portion of a sidewall of the S/D contact structure is covered by the first conductive via.

14. The semiconductor device structure as claimed in claim 11, wherein the first conductive via comprises a first conductive material, and the first conductive material is in direct contact with the first dielectric layer and the second dielectric layer.

15. The semiconductor device structure as claimed in claim 11, wherein the S/D contact structure has a rounded top surface.

16. The semiconductor device structure as claimed in claim 11, further comprising:
a third conductive via formed between the first conductive via and the second conductive via, wherein the third conductive via has a protruding portion extending downwardly from a top surface of the gate structure.

17. A method for forming a semiconductor device structure, comprising:
forming a gate structure over a substrate;
forming a source/drain (S/D) structure adjacent to the gate structure;
forming a first dielectric layer over the gate structure and the S/D structure;
forming an S/D contact structure in the first dielectric layer over the S/D structure;
forming a second dielectric layer over the first dielectric layer;
removing a portion of the second dielectric layer and a portion of the first dielectric layer to form a first trench, wherein the first trench extends into the first dielectric layer, wherein a top surface and a sidewall surface of the S/D contact structure are exposed; and
forming a first conductive via in the first trench, wherein the first conductive via has a protruding portion embedded in the first dielectric layer.

18. The method for forming the semiconductor device structure as claimed in claim 17, further comprising:
forming an etching stop layer over the first dielectric layer, wherein a bottom surface of the first trench is lower than a bottom surface of the etching stop layer.

19. The method for forming the semiconductor device structure as claimed in claim 17, further comprising:
forming a second trench over the gate structure, wherein a bottommost surface of the second trench is lower than a top surface of the gate structure;
forming a second conductive via in the second trench, wherein the second conductive via has a protruding portion extending downwardly from the top surface of the gate structure.

20. The method for forming the semiconductor device structure as claimed in claim 19, further comprising:
forming a conductive layer over the second dielectric layer; and
forming a third conductive via over the conductive layer, wherein the third conductive via has a protruding portion that is lower than a top surface of the conductive layer.
